(19) United States
(12) Patent Application Publication
(10) Pub. No.: US 2005/0223995 A1
(43) Pub. Date: Oct. 13, 2005

(54) Vacuum treatment installation with a variable pump arrangement

(75) Inventors: Andreas Sauer, Grossostheim (DE); Gert Rodling, Obertshausen (DE)

Correspondence Address: KODA & ANDROLIA, 2029 CENTURY PARK EAST, SUITE 1140, LOS ANGELES, CA, 90067, US

(73) Assignee: Applied Films GmbH & Co. KG

(21) Appl. No.: 11/090,579

(22) Filed: Mar. 25, 2005

(30) Foreign Application Priority Data
Mar. 25, 2004 (EP) 04 007 253.0

(51) Int. Cl. B01D 8/00; H05H 1/24; C23C 16/00

(52) U.S. Cl. 118/726; 427/569

(57) ABSTRACT

A vacuum treatment installation, in particular a coating line for the continuous coating of plate-like substrates moving continuously along the line, preferably a glass-coating line having at least one, preferably a plurality of successively arranged vacuum chambers (1) or chamber zones (2 to 8, 17) that are pumped out by means of at least one, preferably a plurality of pumping means (21), with at least one chamber or one chamber Zone being provided at the top of the chamber with a cover (20, 30) to which at least one pumping means is connected, the cover being configured such that it forms a cover space (28) and projects with the cover space over the chamber or the chamber zones.

### BACKGROUND OF THE INVENTION

1. Technical Field

This invention relates to a vacuum treatment installation according to the preamble of claim I and to a removable cover therefor.

2. Description of the Related Art

Vacuum treatment installations and, in particular, coating lines for large-area pane-like or plate-like substrates such as architectural glass, which are moved continuously along the coating line in order to be provided, for example, with thermal insulation layers or the like, are known from prior art. In these installations, in which a large number of chambers are arranged one after the other so that a variety of processing and coating operations can be performed successively, it is necessary to create so-called vacuum conditions, i.e. atmospheres with very low pressures, in the treatment chambers for the coating processes used. To achieve the low process pressures, it is customary to use two different kinds of pumps firstly, turbomolecular pumps, and secondly, diffusion pumps, especially oil diffusion pumps. These pumps, which are used in conjunction with various backing pumps, generate the vacuum or high-vacuum conditions required for the coating processes, and are thus of crucial importance for coating lines.

Prior-art coating lines or vacuum installations, however, are designed for one kind of pump, since turbomolecular and diffusion pumps are configured and operated very differently. Turbomolecular pumps, for their part, can be flanged onto the vacuum installations in a variety of ways, although they are usually mounted upright above the vacuum installation; because of the way they work, diffusion pumps and especially oil diffusion pumps, by contrast, are usually flanged directly onto the process chamber such that they are suspended, or in vertical position. On account of this fixed configuration, and the different nature and location of the pump arrangement, later changes to the positions of the diffusion pumps or even a change from one kind of pump to another are no longer possible. To do this would necessitate opening the chambers of such vacuum installations with an abrasive cutting-off machine, removing the diffusion pumps and replacing them by welding on other plant components.

### BRIEF SUMMARY OF THE INVENTION

The object of this invention is thus to create a vacuum installation and, in particular, a coating line, preferably a glass-coating line, which is variable in respect of the vacuum pumps used and their positioning. In addition, an installation of this kind should be easy to assemble and effective in operation.

This object is established by a vacuum treatment installation having the features of claim I and by a cover arrangement for a process chamber of a vacuum treatment installation, said cover arrangement having the features of claim 11. Useful developments make up the subject matter of the dependent claims.

The inventors recognized that a variable arrangement of pumping means and, in particular, even a change between different types of vacuum pump, ought to be especially easy if the known form of arrangement for tutbomolecular pumps, namely on a removable process chamber cover, were also possible for oil diffusion pumps. This is realized in simple manner according to the invention by configuring a cover of a vacuum treatment chamber or of a chamber zone (compartment) such that the cover encloses a cover space (chamber cover) via which a volume transport from the chamber via the cover is made possible. Through provision in this way of a sufficiently high conductance for the cover, uniform evacuation of the installation by means of diffusion pumps is ensured. The connection means for the diffusion pumps, and in particular the oil diffusion pumps, can be provided at the sides of or on the underside of the cover, with the diffusion pumps being connected by way of appropriate adapters having sufficiently high conductance. The adapter can thus constitute a straight connection or a comer-type connection between the cover and the pump. It is preferable to equip the adapter with a so-called baffle, which, by means of its cooled baffle plates, prevents oil from getting into the cover space.

It is to advantage that the chamber cover with its enclosed cover space projects over the chamber, so that pumps, supply lines and the like can be fitted not only from the top or the side, but in particular also from below. This makes it especially easy to mount oil diffusion pumps directly on the cover, or to mount them thereon via appropriate adapter arrangements, and to deaerate the chamber or compartment under the cover by means of the diffusion pump, especially the oil diffusion pump.

It has proved beneficial here if the cover projects laterally, that is, transverse to the substrate-transport direction, on one, but preferably on both, sides of the chamber, as this makes for a simple arrangement of diffusion pumps, especially on both sides of the chamber, and allows the gas flow in the cover and in the chamber to be adjusted advantageously. It is beneficial to provide the covers with corresponding connection means for the oil diffusion pumps, these connection means being located on the underside of the projecting area and preferably being designed such that they can be closed off if the cover is to be inserted without any diffusion pumps connected to it.

Additional connection means for further pumps, especially turbomolecular pumps, can be provided in like manner on the top of the cover, thus making it possible to use one and the same cover both for turbomolecular pumps and for oil diffusion pumps. It goes without saying that also these connection means for the turbomolecular pumps on the top of the cover should be configured such that they can be closed off in vacuum-tight manner.

Since process tools, too, are customarily inserted via openings at the top of the process chamber, or are mounted on appropriate covers for closure of these openings, the additional or alternative provision of oil diffusion pumps on the same or, preferably, differently configured covers according to the invention, can ensure particularly variable use of the compartments or chambers of a vacuum treatment installation, which compartments or chambers are usually almost identical in their basic design. Depending on the application in question or the configuration of the vacuum treatment installation, the chamber or the compartment is closed with an appropriate cover, e.g. with a flat cover with turbomolecular pumps, a cover provided additionally or alternatively with process tools, or a chamber cover provided additionally or alternatively with diffusion pumps, etc. A rearrangement or conversion is easily accomplished by exchanging the covers for the chambers or chamber zones. If, for example, a chamber is to be pumped out with oil diffusion pumps instead of with turbomolecular pumps, the corresponding cover for turbomolecular pumps is replaced by one for diffusion pumps.

An especially simple cover configuration for forming a gas-transport space or cover space is obtained by using a cuboid-shaped or box-shaped design, in which case, besides the previously mentioned connection means for the pump arrangements, it is only necessary to provide, on the underside of the cover, an appropriate aperture for the connection to the vacuum chamber or compartment of the vacuum chamber.

According to one advantageous embodiment, the cover is provided with at least one throttle valve by means of which the pumping capacity of the connected pumping means can be set and varied. It is thus preferable to provide a separate throttle valve for each connection means accessing a pumping means, which throttle valve can, for example, be located opposite the connection means.

According to another preferred embodiment, the throttle valve has a closure means which can be moved, for example by a linear drive, in relation to the aperture in the connection means, i.e. in relation to the pumping means, and in the extreme case can close off the aperture in the connection means and hence also the access to the pumping means.

In order to pump out different chamber zones or compartment zones with the pumping means connected to the cover, it can be of advantage for the cover to have separating or guide plates (partitions). This is beneficial, for example, if a chamber zone (compartment) is configured as part of a gas-separation stage, and the chamber or chamber zone neighbouring this compartment is pumped out via one part of the compartment while the other part of the chamber is pumped out directly. In this case, partitions corresponding to the partitions in the cover are provided in the compartment, too. According to a preferred embodiment, a partition can be provided that runs almost diagonally in the cover space, thus allowing two different zones to be pumped out via the two laterally disposed pumping means.

Further advantages, characteristics and features of this invention are explained in the following detailed description of preferred embodiments by reference to the enclosed drawings. The drawings are purely diagrammatic in nature.

### BRIEF DESCRIPTION OF THE SEVERAL VIEWS OF THE DRAWINGS

FIG. 1 is a side view in the substrate-transport direction, partially in cross-section, of a glass-coating line;

FIG. 2 is a cross-sectional view, transverse to the transport direction, through the glass-coating line of FIG. 1;

FIG. 3 is a side view in the substrate transport direction, partially in cross-section, of another embodiment of a glass-coating line and/or of a chamber zone, in which view certain components have been left out for the sake of clarity;

FIG. 4 is a view corresponding to that of FIG. 3 but showing some of the components not shown in FIG. 3;

FIG. 5 is a top view of a cover, where the connections for the diffusion pumps are indicated diagrammatically;

FIG. 6 is a top view of a glass-coating-line cover with a partition; the connections for the diffusion pumps are shown diagrammatically.

### DETAILED DESCRIPTION OF THE INVENTION

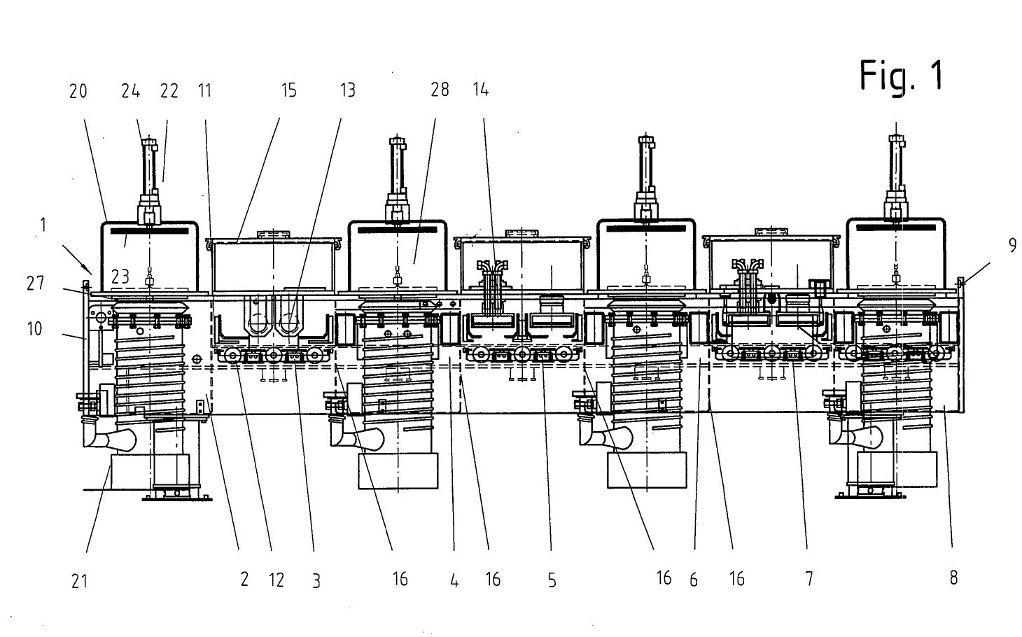

FIG. 1 is a side view, partially in cross-section, of the chamber 1 of a continuous-operation glass-coating line comprising altogether seven compartments 2 to 8 that are essentially of the same basic design. The compartments, which are practically identical in their basic design and can accordingly be used for all purposes, are equipped with various process tools (13 and 14) for a wide variety of stages in the coating process (compartments 3,5 and 7) or else serve as pump compartments (compartments 2, 4, 6 and 8) for the generation of the vacuum conditions required for the coating process in the chamber 1 or the compartments 2 to 8; the pump compartments (2, 4, 6, 8) also pump out the neighbouring process compartments.

For a complete glass-coating line, several such chambers can be arranged in succession, these chambers being interconnected in vacuum-tight manner by way of the chamber walls 9 and 10, which are configured as chamber flanges.

The individual compartments 2 to 8 are separated from one another by partition walls 16 so as to prevent any atmospheric exchange between the individual compartments. Especially where one coating process is followed by a different one, this is essential.

The substrates to be coated are conveyed horizontally through the chamber 1 or compartments 2 to 8 by a transport means configured as a roller conveyor 12; in each of the partition walls 16, a slit-like lock (not shown) is provided, thus enabling the substrates to move continuously through the chamber 1 or the compartments 2 to 8. The substrate-transport plane 11 is indicated in FIG. 1 by a dot-dash line.

Each compartment has an opening at the top, via which the process tools, for example, can be inserted.

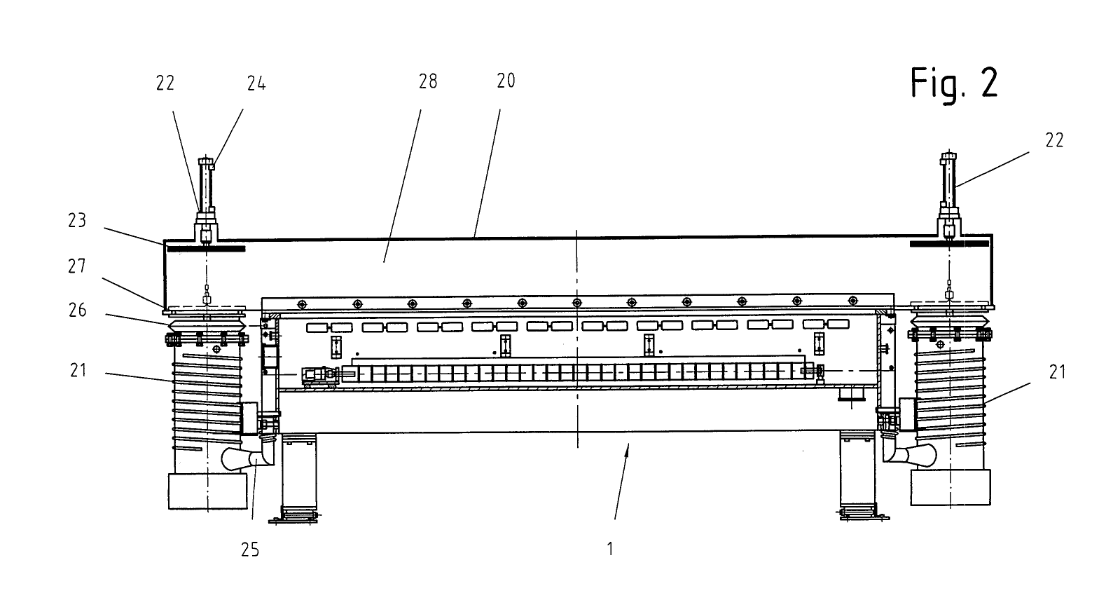

Each of the pump compartments 2,4, 6 and 8 is equipped at the top side of the chamber with a removable cover 20, and each of the process compartments 3, 5 and 7 with a removable cover 15, which covers close off a corresponding opening in the compartment or the chamber 1 in vacuum-tight manner. The cover 15 partially comprises process tools 14. As is especially evident from FIG. 2, in the sectional view transverse to the substrate-transport direction, the cover 20 is designed to be larger than the chamber 1 in the cover's dimension transverse to the substrate-transport direction, so that the cover 20 projects on both sides.

On the underside of each of the projecting areas of the cover 20, an oil diffusion pump 21 is mounted via an adapter 26, a so-called baffle, to a connection means 27 provided in the cover. The connection means 27 includes an aperture that provides a connection between the oil diffusion pump 21 and the space 28 enclosed by the cover 20, as well as means which have not been detailed in the drawing—for connecting the diffusion pump 21, or an adapter 26 provided between the connection means 27 and the diffusion pump 21, in vacuum-tight manner. The adapter or baffle 26 has a baffle plate composed of a plurality of water-cooled lamellae which overlap each other such that a straight connection through the lamellae is prevented (optically obscured) and simultaneously a slight resistance is offered to a gas flow, so that oil vapour from the oil diffusion pump is prevented from entering into the cover or the chamber, but extraction is possible.

The cover space 28 formed by the square-shaped or box-shaped construction of the cover 20 ensures an effectively functioning connection between the oil diffusion pump 21 and the corresponding compartments 2, 4, 6 and 8 of the chamber 1 for the purpose of pumping out the compartments.

To permit variation of the pumping capacity, valve means 22 are provided at the top of the cover 20, opposite the connection means 27. The valves permit throttling of the pumping capacity. For this purpose, the throttle valves 22 have a valve disk 23 which, in the extreme case, can close off the aperture in the connection means 27, as is illustrated by the dashed line in FIGS. 1 and 2. The throttle valve 22 can thus serve also as a closure for the connection means 27.

The valve disk 23 can be moved translatorially in vertical direction by means of a linear drive 24, so that the disk can be raised from and lowered onto the aperture in the connection means 27. In this way, the pumping capacity of the oil diffusion pump 21 can be adjusted as required.

The connections for the oil diffusion pump 21, for example the connection 25 to the backing pump, as well as the connections for the cooling lines, the power supply etc., can advantageously be located laterally along the vacuum chamber 1, in the space which is to the side of the vacuum chamber 1 and is covered by the cover 20. In so far, the configuration of the invention also permits space-saving and protected arrangement of the installation peripherals.

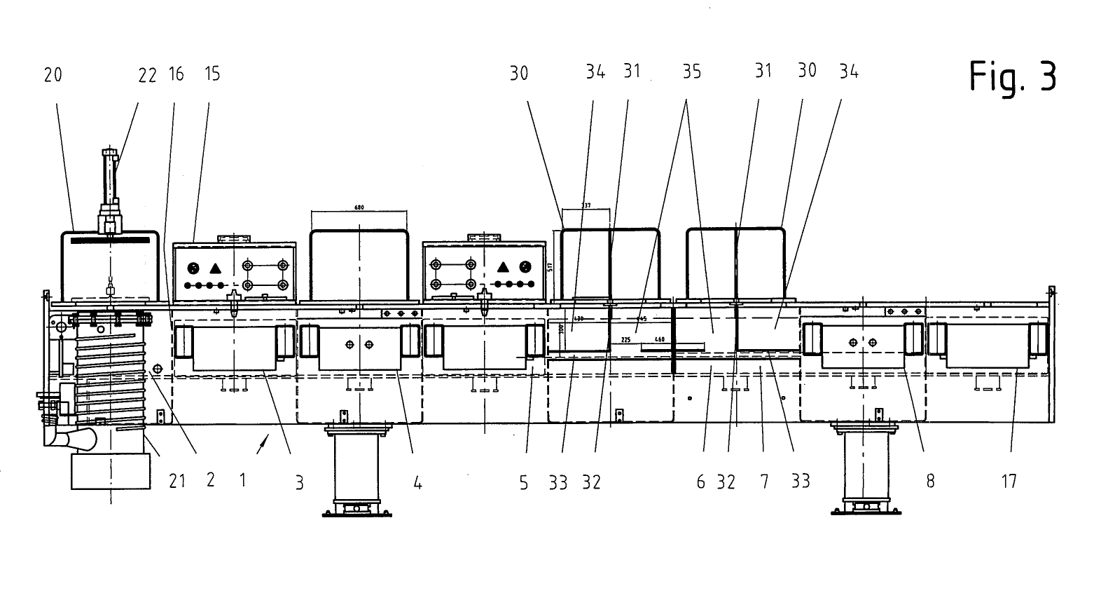

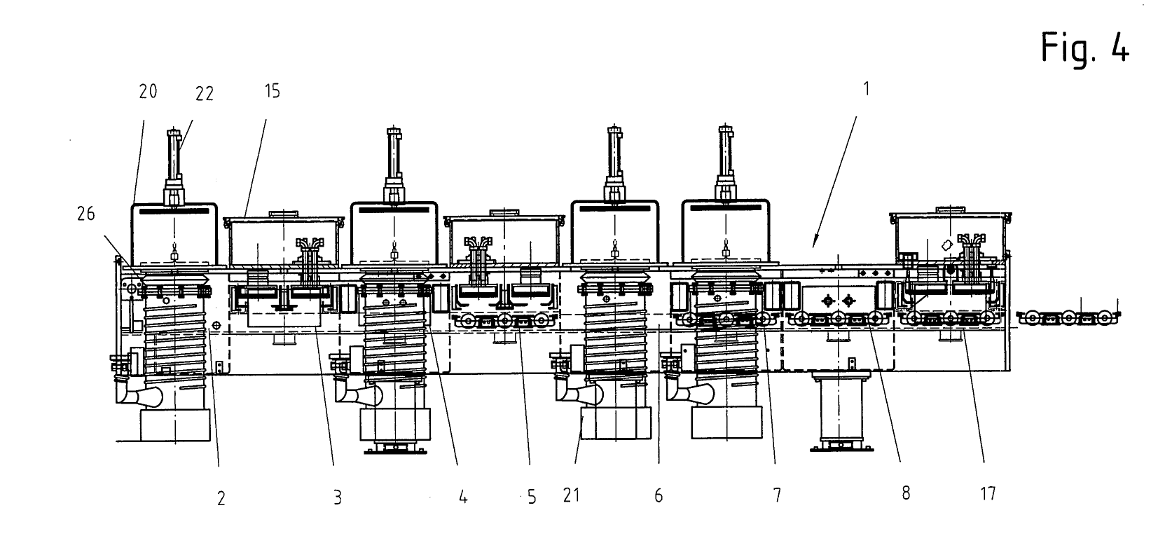

FIG. 3 and 4 are side views, partially in cross-section, illustrating various components of another embodiment of a coating chamber 1 of a glass coating line, the coating chamber 1 having a plurality of compartments 2 to 8 and 17. Many of this chamber's design features are the same as or very similar to those of the embodiment shown in FIGS. 1 and 2, so that the same reference numerals have been used for identical or largely identical components; for the rest, the description focuses principally on the differences.

To start with, the chamber 1 of FIGS. 3 and 4 differs from the embodiment of FIGS. 1 and 2 in that an additional compartment is provided, namely the compartment 17. Apart from this, the main difference is that the adjacent compartments 6 and 7 are configured as a gasseparation stage in order to ensure particularly reliable and highly effective separation of the atmospheric spaces for the neighbouring coating and/or treatment processes in the compartments 5 and 8 and/or 17.

The gas-separation stage in the compartments 6 and 7 is configured such that in each of the covers 30 and of the compartments 6 and 7, a partition wall 31 or 32 is provided that runs transverse to the substrate-transport direction and separates the compartment space or the cover space into two parts.

In each of the compartments 6 and 7, therefore, a compartment space 34 is formed that borders on the neighbouring compartments 5 or 8 and is separated from the rest of the compartment space; in addition to the transport direction, the compartment space 34 is separated off by means of a slit-like lock 33. Via this compartment space 34, which opens to the neighbouring compartments, the neighbouring compartments 5 and 8 are pumped out. The remaining compartment space 35, which borders in each case on the neighbouring compartment 6 or 7, is pumped out separately.

For this purpose, the partition wall 31 in the cover is arranged such that it runs essentially diagonally in the space enclosed by the cover 30 (see FIG. 6), so that the one oil diffusion pump 21 located laterally next to the chamber 1 pumps out the compartment space 34, which is connected with the neighbouring process compartment 5 or 8, and the other oil diffusion pump pumps out the central compartment area 35.

Since the covers 20 and 30 are exchangeable and, moreover, are easily attached to the chamber 1 or to the corresponding compartments 2 to 8 or 17, the compartments 2 to 8 and 17, being identical in their basic design, can easily be converted from a coating compartment or a simple pump compartment into a component compartment of a gas-separation stage, for example by taking off the covers 20 and 15 from the compartments 6 and 7 in the embodiment according to FIG. 1, removing the corresponding tools from the compartments 6 and 7 and replacing them by partition-wall inserts 32 and 33, and then putting on a new gas-separation-stage cover 30. This illustrates how variable a vacuum treatment installation with the innovative cover construction is, especially when one considers that also covers with turbomolecular pumps, diffusion pumps and/or process tools are configured to be exchangeable.

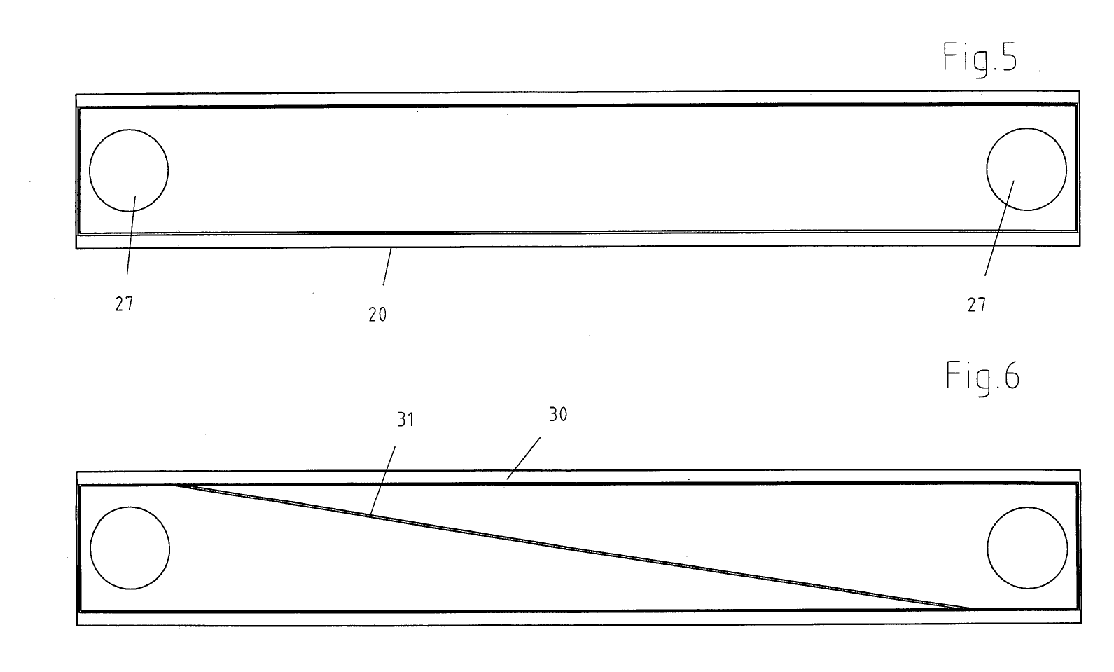

FIG. 5 is a similar view to that of FIG. 6 and illustrates the difference between a cover for a gas-separation stage and a cover for a pump compartment.

1. A vacuum treatment installation, in particular a coating line for the continuous coating of plate-like substrates moving continuously along the line, preferably a glass-coating line having at least one, preferably a plurality of successively arranged vacuum chambers (1) or chamber zones (2 to 8, 17) that are pumped out by means of at least one, preferably a plurality of pumping means (21), with at least one chamber or one chamber zone being provided at the top of the chamber with a removable cover (20, 30) to which at least one pumping means is connected, characterized in that the cover is configured such that it forms a cover space (28) and has at least one connection means for a diffusion pump, preferably an oil diffusion pump.

2. The vacuum treatment installation according to claim 1, wherein the cover with the cover space projects over the chamber or the chamber zones, preferably laterally, transverse to the substrate-transport direction, on at least one, preferably both sides of the chamber.

3. The vacuum treatment installation according to claim 1, wherein at least one connection means (27) for a diffusion pump, preferably an oil diffusion pump (21), is provided on the underside of the cover in the projecting area, said connection means preferably being closable in vacuum-tight manner.

4. The vacuum treatment installation according to claim 1, wherein the cover space (28) in the cover is formed by a cuboid-shaped or box-shaped cover construction, which opens downwards, at least partially, in the area of the vacuum chamber.

5. The vacuum treatment installation according to claim 1, wherein at least one connection means for a turbomolecular pump is provided on the top side of the cover, said connection means preferably being closable in vacuum-tight manner, and/or attachment means for process tools are provided on the underside of the cover.

6. The vacuum treatment installation according to claim 1, wherein the chamber is configured such that different covers can be removably attached to it, thereby closing the chamber in vacuum-tight manner, said covers including: projecting covers with cover space, either with (30) or without (20) separating or guide plates, covers with process tools (15) mounted on the covers, and/or covers with turbomolecular pumps.

7. The vacuum treatment installation according to claim 1, wherein the cover has a throttle valve (22) that is preferably provided opposite the connection means (27) for the pumping means (21) and is preferably formed by a closure lid that can be raised from the connection means, said closure lid being movable relative to the aperture in the connection means by way of a linear drive.

8. The vacuum treatment installation according to claim 1, wherein the cover (30) has at least one partition (31) by means of which the cover space is sub-divided into separate areas that are pumped out separately.

9. The vacuum treatment installation according to claim 8, wherein a partition (31) is arranged to pass diagonally through the cover space so that different zones can be pumped out by way of the pumping means, especially diffusion pumps, located on both sides of the chamber.

10. The vacuum treatment installation according to claim 9, wherein a chamber partition (32) running parallel to the partition in the cover and connected releasably with said cover partition, preferably in essentially gas-tight or vacuum-tight manner, is provided in the chamber in order to form a gas-separation stage.

11. A cover for the chamber of a vacuum treatment installation according to any one of claims 1 through 10, having a cuboid-shaped or box-shaped construction for a formation of a cover space (28) and at least one, preferably two connection means (27) for diffusion pumps (21), preferably oil diffusion pumps, preferably on an underside in a narrow-side area, said cover preferably having one of the characterizing features of claims 5 and 7 through 9.
